(19) United States
(12) Patent Application Publication
(10) Pub. No.: US 2026/0346333 A1
(43) Pub. Date: Nov. 5, 2026

(54) COATED CUTTING TOOL

(71) Applicant: WALTER AG, Tubingen (DE)

(72) Inventors: Jose Luis GARCIA, Tubingen (DE); Dirk STIENS, Tubingen (DE); Christian GOLD, Tubingen (DE); Veit SCHIER, Tubingen (DE)

(21) Appl. No.: 19/488,155

(22) PCT Filed: May 28, 2024
(86) PCT No.: PCT/EP2024/064605

§ 371 Date: Nov. 26, 2025

(30) Foreign Application Priority Data
Jun. 1, 2023 (EP) 23176667.6

(51) Int. Cl. B22F 5/00; B22F 3/24; B22F 7/00; C04B 41/45; C04B 41/50; C04B 41/52

(52) U.S. Cl. CPC B22F 5/00; B22F 3/24; B22F 7/008; C04B 41/4531; C04B 41/5031; C04B 41/5057; C04B 41/5068; C04B 41/52; B22F 2003/242; B22F 2005/001; B22F 2207/05; C04B 2235/3847

(57) ABSTRACT

The present invention relates to a coated cutting tool including a substrate of cemented carbide and a coating. The cemented carbide includes WC grains and eta phase grains and metallic binder. The metallic binder includes Co, Cr and Ti. The eta phase content in the cemented carbide is 1-10 vol %, the average grain size of the eta phase grains is 0.5-5 μm and the thickness of the coating is 1-15 μm.

### TECHNICAL FIELD

The present invention relates to a coated cutting tool. The cutting tool is coated with a wear resistant coating and the substrate is a cemented carbide wherein the cemented carbide comprises WC, eta phase, Co, Cr and Ti.

### BACKGROUND

Cutting tools of cemented carbide for metal cutting applications are known in the art. Cemented carbide is a material comprising a hard phase that is usually a carbide such as WC, cemented in a metallic binder that usually comprises Co. The composition of the cemented carbide can be adjusted to fit the specific demands that the cutting tool is exposed to in machining a special type of material or a specific type of machining.

Some cutting applications are very demanding for the substrate, applications where the substrate tend to crack which then limits the lifetime of the cutting tool. Examples of very substrate demanding cutting applications are milling and turning in stainless steels and in titanium alloys. These workpiece materials tend to stick to the surface of the tool and build up a built-up edge that, when it is too large, breaks off and then sometimes rip off a part of the cutting edge. The cutting edges are further exposed to high temperatures during the metal cutting in stainless steels and in titanium alloys.

It is known to add ruthenium (Ru) into the Co binder phase of cemented carbide, herein called Ru-alloyed cemented carbide. This results in a cemented carbide substrate with an improved resistance to thermal cracking and reduction of propagation of cracks into the substrate during the metal machining processes. The high temperature properties of the cemented carbide are then improved. The amount of Ru may vary depending on the application and is normally within 5 wt %-25 wt % of the metallic binder.

Ru is a raw material that is rare and very expensive. It is also complicated to recycle Ru as part of the recycling of cemented carbide materials. There is need to replace the high performing Ru-alloyed cemented carbides in metal cutting tools.

It is an object of the present invention to provide a coated cutting tool for metal cutting applications with wear resistance properties as high performing as an Ru-alloyed cemented carbide. It is a further object to provide a coated cutting tool that shows high wear resistance in cutting in stainless steel and in titanium alloys. It is also an object of the present intention to provide a cutting tool with a long lifetime in milling applications.

### DESCRIPTION OF THE INVENTION

At least one of the above-mentioned objects is achieved by a cutting tool according to claim 1. Preferred embodiments are disclosed in the dependent claims.

The present invention relates to a substrate of cemented carbide and a coating, wherein the cemented carbide comprises WC grains and eta phase grains and metallic binder, wherein the metallic binder comprises Co, Cr and Ti, the Co content in the cemented carbide is 6-16 wt %, the Cr/Co weight ratio in the cemented carbide is 2%-12%, the Ti/Co weight ratio in the cemented carbide is 0.04%-0.20%, the eta phase content in the cemented carbide is 1-10 vol %, the average grain size of the eta phase grains is 0.5-5 μm, the thickness of the coating is 1-15 μm.

It has surprisingly been found that the cutting tool in accordance with the present invention has a similar performance and can therefore replace Ru-alloyed cemented carbide cutting tools.

The cutting tool as disclosed herein can for example be an insert or an endmill designed for milling applications.

The cemented carbide of the present invention comprises WC grains and eta phase grains embedded in a metallic binder. The metallic binder comprises Co, Cr, Ti and also W that is dissolved into the metallic binder from the WC grains during the sintering of the cemented carbide.

By a coating on the cutting tool is herein meant a coating that is deposited on the cemented carbide substrate to increase the wear resistance of the cutting tool. This coating can for example be a coating deposited with Physical Vapour Deposition (PVD) or Chemical Vapour Deposition (CVD).

The Co content in the cemented carbide of the present invention is 6-16 wt % Co. If the Co content is lower than 6 wt % the cutting tool will lose in toughness properties. If on the other hand the Co content is higher than 16 wt % the cutting tool will lose in comb crack resistance and become prone to plastic deformation of the cutting edge. A Co content higher than 16 wt % will also make the cutting tool sensitive to chemical attacks by a cooling media used in milling application and by the work piece material during the cutting.

The eta phase content in the cemented carbide of the present invention is 1-10 vol %. If the eta phase content is too high a large part of the Co content in the metallic binder is consumed into the eta phase grains and this would make the cemented carbide too brittle. If the eta phase content is too low there is an increased risk that the eta phase grains forms clusters and these are brittle instead of the well distributed eta grains.

The Cr content in the cemented carbide of the present invention is such that Cr (wt %)/Co (wt %) is 2-12%. It was surprisingly found that this content of Cr in the cemented carbide improved the cutting tool properties. With Cr added in the cemented carbide the eta phase grains will include Cr. Cr will also remain in solid solution in the metallic binder phase comprising Co. Cr will also act as a grain growth inhibitor during the sintering and restrict continued growth and coarsening of the WC grains. If the Cr content is too low Cr will still effect the WC grain size growth, but the solid solution will be limited. If the Cr is too high unwanted Cr-carbides (such as M₇C₃) may form, causing embrittlement of the cemented carbide. The cemented carbide with the Cr content within the weight ratio range Cr/Co 2-12% has due to the solid solution effect a high strengthening. The work hardening properties of Co is improved, the hot hardness properties are considered to be improved, and also chemical resistance, i.e. corrosion resistance is considered to be improved due to the Cr content of the present invention.

The cemented carbide according to the present invention has a low carbon content so that eta phase grains are formed. This will result in a cemented carbide having both a W content in the binder and eta phase grains. By eta phase is herein meant carbides selected from Me₁₂C and Me₆C where Me is one or more metals selected from W and the binder phase metal or metals so the carbides could be (W,Co,Cr)₆C and/or (W,Co,Cr)₁₂C.

In the present invention the cemented carbide comprises fine dispersed eta phase grains. By fine dispersed is herein meant that the cemented carbide microstructure does not contain more than 8 clusters or eta phase grains larger than 15 μm in an area of 1 mm² in a light optical microscope image at 200 times magnification. Eta phase grains can exist as very large, brittle and unwanted form with grain sizes typically above 50 μm or even larger than 100 μm and these are not part of the present invention. The eta phase grains of the present invention are 0.5-5 μm in average grain size and these grains are evenly distributed within the metallic binder of the cemented carbide. The fine dispersed eta phase grains of the present invention are formed during the sintering process and carbon deficiency and equilibrium temperature needs to be controlled in the process to reach the claimed eta phase appearance and content. The difference in substoichiometric carbon content between achieving the unwanted large agglomerates of eta phase, and achieving the finely distributed eta phase, that it is aimed for, can be very small. Being close to that limit requires monitoring the microstructure to make sure that the unwanted large agglomerates are avoided. Carefully adjusting carbon contents and then monitor its result in terms of the obtained microstructure is a known working procedure to a person skilled in the art.

It was surprisingly found that the combination of the addition of the specific content of Cr and the addition of Ti in the specified low levels can be used to achieve an advantageous grain size and grain size distribution of the eta phase grains in a cemented carbide comprising fine dispersed eta phase. The presence of the small amounts of Ti as defined surprisingly gives the effect of higher hardness while the toughness is kept at about the same level.

In one embodiment of the present invention the cemented carbide comprises 75-91 vol % WC, preferably 75-85 vol % or 80-87 vol % WC.

In one embodiment of the present invention the cemented carbide consists of WC grains and eta phase grains in a metallic binder of Co, Cr and Ti and wherein some Wis dissolved in the metallic binder. W will inevitably be dissolved in the metallic binder during sintering and the exact amount depends on several things, such as the overall composition of the cemented carbide, the exact carbon content etc.

In one embodiment of the present invention the average WC grain size is 0.30-1.00 μm. The average WC grain size can be measured by e.g. image analysis.

In one embodiment of the present invention the Co content in the cemented carbide is 10-15 wt %, preferably 12-14 wt %.

In one embodiment of the present invention the Cr/Co weight ratio in the cemented carbide is 2%-10%, preferably 2%-4% or 8%-10%.

In one embodiment of the present invention the Ti/Co weight ratio in the cemented carbide is 0.05%-0.16%.

In one embodiment of the present invention the eta phase content in the cemented carbide is 1-5 vol %, preferably with a Cr/Co weight ratio in the cemented carbide of 2%-4%.

In one embodiment of the present invention the eta phase content in the cemented carbide is 5-10 vol % preferably with a Cr/Co weight ratio in the cemented carbide of 8%-10%.

In one embodiment of the present invention the average grain size of the eta phase grains is 0.5-3 μm, preferably 1-2 μm.

In one embodiment of the present invention the thickness of the coating is 2-10 μm.

In one embodiment of the present invention the average WC grain size is 0.40-0.95 μm. In one embodiment of the present invention the content of eta phase in a portion of the substrate adjacent to the surface of the substrate corresponds to the content of eta phase in the innermost portion of the substrate. The eta phase distribution is thus the same throughout the whole cemented carbide substrate. By that is herein meant that the cemented carbide does not comprise any gradients of eta phase or zones without eta phase, like e.g. in U.S. Pat. No. 4,843,039.

In one embodiment of the present invention the coating is a PVD coating. In one embodiment of the present invention the PVD coating is a multilayer comprising sublayers of TiAlN and of Al₂O₃. In one embodiment of the present invention the PVD coating comprises a lower TiAlN layer with a thickness 1-3 μm, an Al₂O₃ layer with a thickness of 0.2-1 μm, a (TiAlN+Al₂O₃) multilayer with a sublayer thickness of each of TiAlN and Al₂O₃ of 0.1-0.2 μm, a TiAlN layer of 0.3-0.7 μm and an outer layer sequence of Al/Al₂O₃/ZrN with sublayer thicknesses 10-30 nm/10-30 nm/50-100 nm.

In one embodiment of the present invention the coating is a CVD coating. In one embodiment of the present invention the coating is a CVD coating comprising a lower TIN layer with a thickness 0.05-2 μm, a TiAlN layer with a thickness of 1-14 μm, preferably the coating also comprises an upper TiN layer with a thickness of 0.05-2 μm.

In one embodiment of the present invention the coated cutting tool is a cutting tool insert, a drill, or a solid end-mill, for metal machining.

In one embodiment of the present invention the coated cutting tool comprises a substrate of cemented carbide and a coating, wherein the cemented carbide comprises Co, Cr and Ti and eta phase grains and balance WC, wherein the Co content in the cemented carbide is 6-16 wt %, the Cr/Co weight ratio in the cemented carbide is 2-4%, the Ti/Co weight ratio in the cemented carbide is 0.04%-0.20%, the eta phase content in the cemented carbide is 1-5 vol %, the average grain size of the eta phase grains is 0.5-3 μm and the thickness of the coating is 1-15 μm.

In one embodiment of the present invention the coated cutting tool comprises a substrate of cemented carbide and a coating, wherein the cemented carbide comprises WC grains and eta phase grains and metallic binder, wherein the metallic binder comprises Co, Cr and Ti, the Co content in the cemented carbide is 6-16 wt %, the Cr/Co weight ratio in the cemented carbide is 2-4%, the Ti/Co weight ratio in the cemented carbide is 0.04%-0.20%, the eta phase content in the cemented carbide is 1-5 vol %, the average grain size of the eta phase grains is 0.5-3 μm and the thickness of the coating is 1-15 μm.

In one embodiment of the present invention the cemented carbide consists of 75-85 vol % WC grains and 1-10 vol % eta phase grains and balance vol % metallic binder. The area fraction in the image is herein considered to correspond to represent the volume fraction.

### Methods

The cemented carbide of the present invention is made in accordance with normal cemented carbide manufacturing methods. The steps of milling, drying, pressing and sintering are used.

The carbon content needs to be adjusted during the cemented carbide manufacturing to achieve the correct eta phase content.

The formation of evenly or finely distributed eta phase grains in accordance with the present invention is achieved by controlling the carbon content carefully during the cemented carbide manufacturing. The cemented carbide in the present invention is has a substoichiometric carbon content within a certain range. Substoichiometric carbon is a measure of the carbon content in relation to the stoichiometric carbon content.

Suitably the carbon content is between −0.40 and −0.16 wt % substoichiometric carbon, preferably between −0.35 and −0.17 wt % substoichiometric carbon.

The stoichiometric carbon content may be calculated by assuming that the carbides in the cemented carbide are completely stoichiometric, for example the atomic ratio W:C is assumed to be 1:1. Since other carbide forming elements are present in the cemented carbide, such as Cr, the corresponding carbide Cr₃C₂, is also assumed to be stoichiometric.

This means that the term substoichiometric carbon, as used herein, is the total carbon content in the cemented carbide determined by chemical analysis minus the calculated stoichiometric carbon content based on WC and possible other carbides present in the cemented carbide. In the sintered cemented carbide:

[Carbon content]=[stoichiometric carbon content]+[subsoichiometric carbon content]

As an example, if the stoichiometric carbon content for a particular cemented carbide is 5.60 wt %, and this cemented carbide would be made with a carbon content of 5.30 wt %, the substoichiometric carbon content would be-0.30 wt %.

To achieve the correct carbon content in the final sintered cemented carbide manufacturing, W and/or W₂C is added in such amounts that the desired substoichiometric carbon is achieved. The cemented carbide has such a low carbon content that eta phase is formed. The eta phase formed is, however, not present as large grains or agglomerates but is of a fine grain size and well distributed. The desired form of eta phase is provided by controlling the carbon balance carefully during manufacturing.

If the carbon content in the sintered cemented carbide is too low, i.e. lower than −0.40 wt % substoichiometric carbon content, the amount of eta phase becomes too large and the particle size increases considerably so the cemented carbide will be brittle. On the other hand, if the carbon content is higher than −0.16 wt % substoichiometric carbon content but still in the eta phase forming region, the formed eta phase will be unevenly distributed in the form of large agglomerates leading to a decrease in toughness of the cemented carbide.

The carbon content is to be measured on the sintered cemented carbide, since some of the carbon will be lost during sintering due to the formation of e.g. CO₂. The exact amount of carbon lost depends on the specific sintering furnace and sintering process. The powder will thus have a small excess of carbon compared to what is aimed for in the sintered cemented carbide. Typically the substoichiometric carbon value in the sintered material is about 5-25% lower than the substoichiometric carbon value in the powder composition. For example, a substoichiometric carbon value in the powder composition of-0.20 wt % may give a substoichiometric carbon value in the sintered material of from about-0.21 wt % to about-0.25 wt %. Carbon content in the sintered cemented carbide or the powder can for example be measured by the LECO CS844 instrument. It is up to the person skilled in the art to adjust the W and/or W₂C additions so that the aimed eta content in the cemented carbide is achieved.

The amount of eta phase in the cemented carbide was determined by image analysis of LOM (light optical microscope) images at 2000×. The area fraction in the image is considered to correspond to the volume fraction in the cemented carbide. The volume fraction of WC can be determined in the corresponding way as the eta phase volume fraction.

The average grain size of the WC grains is herein measured using the Saltykov method on an image of a cross section of the substrate. The test area is a square with a size such that at least 50 grains but not more than 100 grains are included. At least 700 grains should be

$${N}_{A} = \frac{{M}^{2}}{A} ( {N}_{i n s i d e} + \frac{1}{2} * {N}_{intercepted} + 1 )$$

wherein M is the magnification used and A is the area of the test square. N_{intercepted} is the number of grains intercepted by the test squares' sides. A grain intercepted at the corner of the test square counts as one fourth of a grain. N_{inside} is the number of whole grains inside the test square. The average grain size of WC, d_{WC}, can then be determined by

$${d}_{WC} = \sqrt{\frac{1}{{N}_{A}}}$$

The average grain size of the eta phase grains is herein defined as the average value of the maximum Feret diameter of the eta phase grains. This value can be determined by, e.g., image analysis on a light optical microscope (LOM) image.

The chemical composition of the cemented carbide can for example be measured by chemical analysis with XRF (X-ray fluorescence) using a Panalytical Axios Max Advanced instrument.

The layer thicknesses in the coating were measured in a polished cross section in an SEM image.

The hardness and the toughness of the cemented carbide was measured using Vickers indentation.

### BRIEF DESCRIPTION OF DRAWINGS

Embodiments of the invention will be described with reference to the accompanying drawings.

FIG. 1 shows a schematic view of one embodiment of a cutting tool (1) with geometry ADMT 160608 having a rake face (2) and flank faces (3) and a cutting edge (4). The cutting tool (1) is in this embodiment a milling insert.

FIG. 2 shows a drawing of a cutting tool (1) with the geometry ROHX1204.

FIGS. 3-5 shows LOM (Light Optical Microscope) cross-sections of samples further presented in the Example section below.

FIG. 3 shows LOM cross-sections of a) sample Reference 1, b) sample Invention 1, c) sample Invention 2.

FIG. 4 shows LOM cross-sections of a) sample Reference 2, b) sample Invention 3, c) sample Invention 4.

FIG. 5 shows LOM cross-sections of a) sample Reference 3, b) sample Invention 5, c) sample Invention 6.

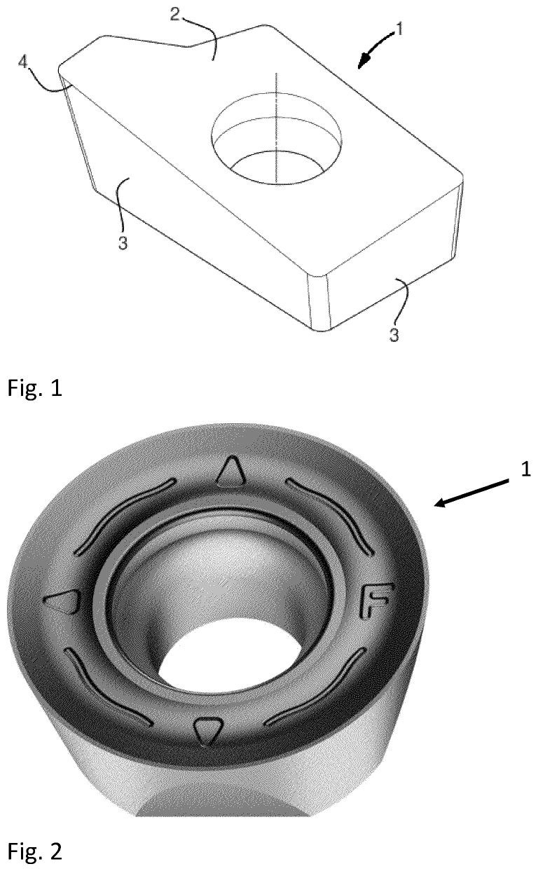

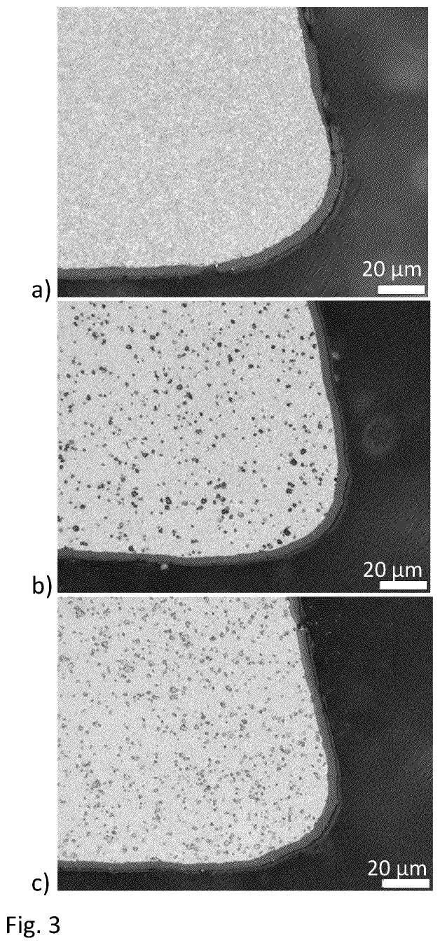

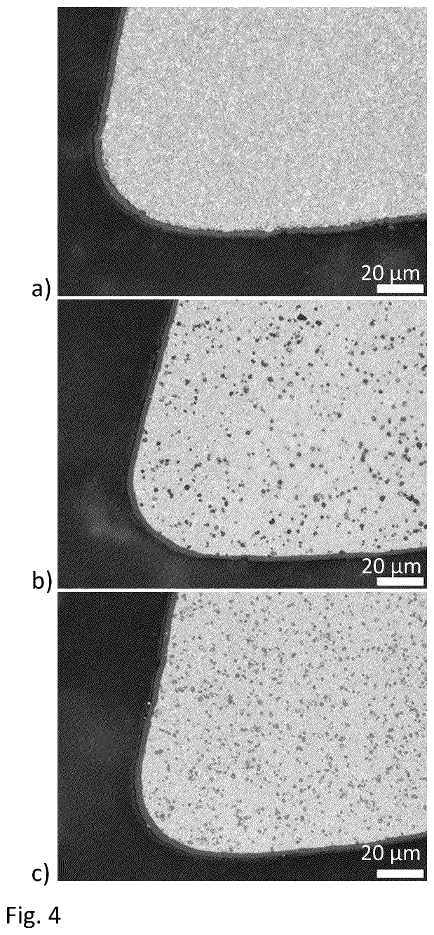

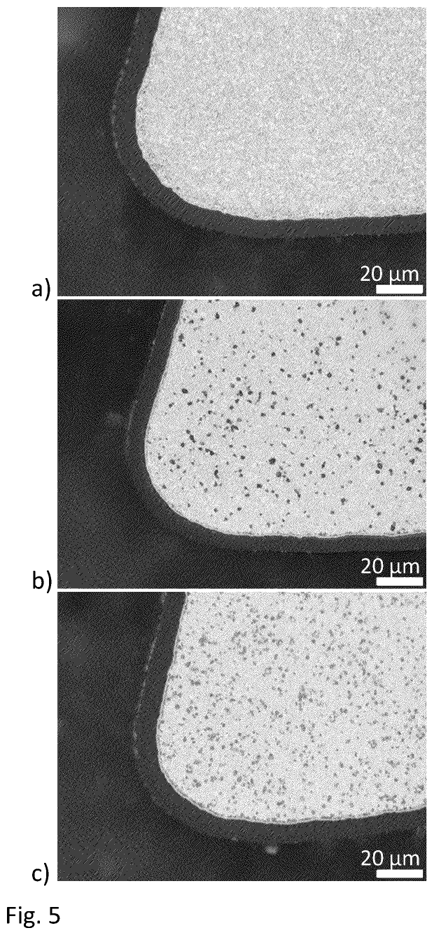

### EXAMPLES

Exemplifying embodiments of the present invention will now be disclosed in more detail and compared to reference embodiments. Coated cutting tools (inserts) were manufactured and analysed and evaluated in cutting tests.

### Substrates

Cemented carbide substrates of two different milling insert geometries ADMT160608R-F56 and ROHX1204M0-F67 were manufactured.

The cemented carbides were made from raw material powders in accordance with Table 1.

TABLE 1
Powder composition

| | WC | Cr₃C₂ | Co | TiC | W | Ru |
|---|---|---|---|---|---|---|
| Sample | [wt %] | [wt %] | [wt %] | [wt %] | [wt %] | [wt %] |
| 1A | 82.59 | 0.46 | 13.09 | 0.012 | 3.85 | — |
| 1B | 83.48 | 0.46 | 13.46 | 0.03 | 2.57 | — |
| 1C | 83.51 | 0.46 | 13.46 | — | 2.57 | — |
| 2A | 79.48 | 1.44 | 13.57 | 0.013 | 5.50 | — |
| 2B | 80.86 | 1.44 | 13.57 | 0.03 | 4.10 | — |
| 2C | 80.89 | 1.44 | 13.57 | — | 4.10 | — |
| 3 | 89.10 | 0.00 | 9.50 | — | 0.00 | 1.4 |

The powders were milled in a ball mill together with a milling liquid (water/ethanol with a ratio of 9/91) and an organic binder, 2 wt % PEG. The amount of PEG is not included in the dry powder weight presented in Table 1. After the milling the slurry was dried. The dried agglomerates were then pressed into a green body. The green body was sintered in 40 mbar in Ar and CO at 1410 °C.

The average content of the eta phase was determined by counting its area in LOM (light optical microscope) images taken at ×2000 using the software Image J and “Analyze particles” function with “include holes” and “0-Infinity” filter settings. Prior to measurements, images were converted into 8-bit black and white images using Automatic threshold setup. The area fraction was assumed to correspond to the volume fraction in the sample. An average value from 10 images is shown in Table 2.

The average particle size of the eta phase grains is herein calculated in the same software as being the average maximum Feret diameter of the eta particle grains. When measuring the maximum Feret diameter the filters “0.01-Infinity” and “exclude on edges” were additionally activated in “Analyze particles” function and only images with 2000× magnification were used. Prior to measurements, images were converted into 8-bit black and white images using Automatic threshold setup. An average value from 6 images is shown in Table 2.

The substoichiometric carbon content in the sintered cemented carbide was calculated by first measuring the total carbon content in the sintered cemented carbide by using a LECO CS844 instrument, for this analysis, the sample was crushed prior to the analysis. The accuracy of the values is ±0.01 wt %. The W, Co and Cr content is measured with XRF (X-ray fluorescence) using a Panalytical Axios Max Advanced instrument. By subtracting the cobalt, the chromium and carbon amounts from the total weight of the sample, the W content is achieved which is used to calculate the stoichiometric carbon content, assuming the WC has a 1:1 ratio. By subtracting the stoichiometric carbon content from the total carbon as measured by the LECO CS844 instrument, the substoichiometric carbon value is achieved. The substoichiometric carbon value in the sintered material differs from that in the powder. This is due to that some of the carbon reacts with oxygen and outgas as CO or CO₂ during sintering, and this reduces the total final C content of the cemented carbide. The carbon in the powder was adjusted to achieve the desired microstructure in the sintered cemented carbides.

The eta phase content and the average grain size of the eta phase grains were measured in accordance with the methods herein disclosed, see Table 2. The eta phase grains in the samples containing eta phase were evenly distributed through the whole substrate body, no gradient in eta phase content was observed in the samples. No gamma phase grains, no very large eta phase grains and no graphite was found in the cemented carbide.

The average grain size of the WC, the eta phase grains and the volume fraction of eta phase of the sintered cemented carbide are presented in Table 2.

TABLE 2
Sintered cemented carbide

| | | | WC | Eta | |
|---|---|---|---|---|---|
| | | | average | phase | |
| | Cr/Co | Ti/Co | grain | grain | Eta |
| | ratio | ratio | size dWC | size | phase |
| Substrate | [%] | [%] | [μm] | [μm] | [vol %] |
| 1A | 3.00 | 0.075 | n.a | 1.5 | 4.5 |
| 1B | 3.00 | 0.15 | 0.92 | 1.5 | 1.53 |
| 1C | 3.00 | — | 1.07 | 1.6 | 1.27 |
| 2A | 9.20 | 0.075 | n.a. | 1.4 | 8.4 |
| 2B | 9.20 | 0.15 | 0.90 | 1.3 | 6.60 |
| 2C | 9.20 | — | 1.02 | 1.3 | 5.49 |
| 3 | — | — | 0.9 | — | — |

Hardness and toughness were measured in accordance with the method disclosed above and the achieved values are presented in Table 3.

TABLE 3
Hardness and toughness of cemented carbide

| | Hardness | K1C |
|---|---|---|
| Substrate | [HV30] | [MN/m^{3/2}] |
| 1A | 1414 | 12.1 |
| 1B | 1433 | 12.3 |
| 1C | 1392 | 14.7 |
| 2A | 1480 | 11.4 |
| 2B | 1491 | 11.1 |
| 2C | 1435 | 12.7 |
| 3 | 1330 | 15.7 |

The inventive samples showed higher hardness compared to the reference samples. The K1C levels of the inventive samples are lower than the reference samples, but all samples have high K1C levels.

Coating PVD TiAlN/Al₂O₃ Multilayer

Substrates 1A, 1B, 2A, 2B and 3 were coated in a PVD process, thereby forming samples Invention 1, Invention 2, Invention 3, Invention 4, Reference 1 and Reference 2. A similar PVD coating is disclosed in the patent application EP1762637A2.

A first inner layer of TiAlN with a thickness of 2 μm with a Al:Ti ration of 67:33. The crystal structure is mainly cubic, only minor amount of hexagonal AlN phase.

Thereafter a layer of nanocrystalline γ-Al₂O₃ with a thickness of 0.5 μm.

On top of the γ-Al₂O₃ layer is a 0.7 μm in thickness multilayer deposited wherein said multilayer consist of the layer sequence TiAlN/γ-Al₂O₃/TiAlN/γ-Al₂O₃. The TiAlN has an atomic ratio Al:Ti of 67:33. All the four layers has about the same layer thicknesses i.e. about 0.175 μm each.

Thereafter a layer of TiAlN with a thickness of 0.55 μm with an atomic ratio Al:Ti of 67:33.

An outermost sublayer sequence of Al/Al₂O₃/ZrN with a sublayer thickness of 20 nm/20 nm/80 nm is finally deposited.

The total thickness of the PVD coating was about 4 μm as measured on the flank face of the cutting tool.

Substrates 1A, 2A and 3 with the geometry ADMT160608R-F56 deposited with the PVD coating formed samples Invention 1, Invention 2 and Reference 1.

Substrates 1A, 2A and 3 with the geometry ROHX1204M0-F67 deposited with the PVD coating formed samples Invention 3, Invention 4 and Reference 2.

### Coating CVD TiN/TiAlN/TiN

Substrates 1A, 2A and 3 with geometry ROHX1204M0-F67 were coated in a CVD process, thereby forming samples Invention 5, Invention 6 and Reference 3. A similar CVD coating is disclosed in patent application WO2017/0216826.

First an inner about 0.7 μm thick TiN layer was deposited at 850 °C.

Thereafter a TiAlN layer was deposited at about 700 °C. The thickness of the TiAlN layer was about 8 μm.

After this, the prepared cutting inserts were subjected to a period of heat treatment. The temperature was increased to 850 °C. After 10 minutes temperature stabilization, a 0.3 μm top layer of TiN was deposited. The total heat treatment time at 850 °C, including the top TiN layer deposition, was 3 hours and 12 minutes.

A summary of the coated samples is presented in Table 4.

TABLE 4
Summary of coated samples

| Sample | Substrate | Coating | Geometry |
|---|---|---|---|
| Invention 1 | 1A | PVD TiAlN/Al₂O₃multilayer | ADMT160608 |
| Invention 2 | 2A | PVD TiAlN/Al₂O₃multilayer | ADMT160608 |
| Reference 1 | 3 | PVD TiAlN/Al₂O₃multilayer | ADMT160608 |
| Invention 3 | 1A | PVD TiAlN/Al₂O₃multilayer | ROHX1204 |
| Invention 4 | 2A | PVD TiAlN/Al₂O₃multilayer | ROHX1204 |
| Reference 2 | 3 | PVD TiAlN/Al₂O₃multilayer | ROHX1204 |
| Invention 5 | 1A | CVD TiN/TiAlN/TiN | ROHX1204 |
| Invention 6 | 2A | CVD TiN/TiAlN/TiN | ROHX1204 |
| Reference 3 | 3 | CVD TiN/TiAlN/TiN | ROHX1204 |

The coated samples were evaluated in cutting tests.

### Performance Testing

Cutting tests were made in order to determine the performance of the samples presented above.

The following expressions/terms are commonly used in metal cutting and are used below:
Vc (m/min): cutting speed in meters per minute
fz (mm/tooth): feed rate in millimeter per tooth (in milling)
z: (number) number of teeth in the cutter
ae (mm): radial depth of cut in millimeter
ap (mm): axial depth of cut in millimeter

### Cutting Test 1

The cutting tools of geometry ADMT160608R-F56 were tested in a shoulder milling operation with workpiece material of Ti6Al4V, a high strength titanium alloy. The cutting speed Vc was 40 m/min, the feed rate, fZ, was 0.12 mm/tooth, the number of teeth in the cutter, z, was 4, the depth axial of cut, ap, was 2.0 mm and the radial depth of cut, ae, 18.0 mm. Water miscible cutting fluid was used. The machining was continued until the end of lifetime criterion was reached. The tool life criterion was set to width of wear of the rake face, Vb max>0.3 mm, on the main cutting edge. Defined intervals were used for the evaluation of the tool wear. The average results of 4 parallel cutting tests per type of sample are presented in Table 5.

TABLE 5

| Milling | Reference 1 | Invention 1 | Invention 2 |
|---|---|---|---|
| distance [mm] | Vb max [mm] | Vb max [mm] | Vb max [mm] |
| 3000 | 0.13 | 0.09 | 0.12 |
| 6000 | 0.18 | 0.10 | 0.13 |
| 7500 | 0.21 | 0.14 | 0.14 |
| 9000 | — | 0.15 | 0.17 |
| 12000 | — | 0.19 | — |

The width of wear on the rake face was significantly lower for the cutting tools of Invention 1 and 2 compared to the ruthenium containing Reference 1.

### Cutting Test 2

The cutting tools ROHX1204M0-F67 (Round insert) were tested in milling operation of turbine blades from a rectangular bar (100×60×400 mm) workpiece material of 1.4913, a heat resistant stainless steel. The cutting speed vC was 240 m/min, the feed rate, fZ, was 0.3 mm/tooth, the number of teeth in the cutter, z, was 5, the depth axial of cut, ap, was 3.0 mm and the radial depth of cut, ae, 32.0 mm. No cutting fluid was used. The machining was continued until the end of lifetime criterion was reached. The tool life criterion was set to width of wear of the rake face, Vb max>0.5 mm, on the main cutting edge. Defined intervals were used for the evaluation of the tool wear and the number of cuts at Vb max. The average results of 5 parallel cutting tests per type of sample are presented in Table 6.

TABLE 6

| | Number | Tool life | Total chip volume |
|---|---|---|---|
| Sample | of cuts | [min] | [cm³/min] |
| Reference 2 | 18 | 39 | 2798 |
| Invention 3 | 28 | 60 | 4287 |
| Invention 4 | 30 | 64 | 4523 |
| Reference 3 | 30 | 65 | 4644 |
| Invention 5 | 30 | 64 | 4522 |
| Invention 6 | 33 | 72 | 5113 |

The number of cuts, the tool life and the total chip volume were significantly higher for the PVD coated cutting tools of invention 3 and 4 compared to the Ru containing Reference 2.

The number of cuts, the tool life and the total chip volume were on the same high level for the CVD coated cutting tools of invention 5 and 6 compared to the Ru containing Reference 3.

1. A coated cutting tool comprising a substrate of cemented carbide and a coating, wherein the cemented carbide comprises WC grains and fine dispersed eta phase grains and metallic binder, wherein the metallic binder comprises Co, Cr and Ti, a Co content in the cemented carbide is 6-16 wt %, a Cr/Co weight ratio in the cemented carbide is 2%-12%, a Ti/Co weight ratio in the cemented carbide is 0.04%-0.20%, an eta phase content in the cemented carbide is 1-10 vol %, an average grain size of the eta phase grains is 0.5-5 μm, and wherein a thickness of the coating is 1-15 μm.

2. The coated cutting tool of claim 1, wherein an average WC grain size is 0.30-1.00 μm.

3. The coated cutting tool in accordance with claim 1, wherein the Co content in the cemented carbide is 10-15 wt %.

4. The coated cutting tool in accordance with claim 1, wherein a Cr/Co weight ratio in the cemented carbide is 2%-10%.

5. The coated cutting tool in accordance claim 1, wherein a Ti/Co weight ratio in the cemented carbide is 0.05%-0.16%.

6. The coated cutting tool in accordance with claim 1, wherein the average grain size of the eta phase grains is 1-2 μm.

7. The coated cutting tool in accordance with claim 1, wherein the thickness of the coating is 2-10 μm.

8. The coated cutting tool in accordance with claim 1, wherein an average WC grain size is 0.40-0.95 μm.

9. The coated cutting tool in accordance with claim 1, wherein the content of eta phase in a portion of the substrate adjacent to a surface of the substrate corresponds to the content of eta phase in an innermost portion of the substrate.

10. The coated cutting tool of claim 1, wherein the coating is a PVD coating.

11. The coated cutting tool of claim 10, wherein the PVD coating is a multilayer comprising sublayers of TiAlN and of alumina.

12. The coated cutting tool of claim 10, wherein the coating includes a lower TiAlN layer with a thickness 1-3 μm, an Al₂O₃ layer with a thickness of 0.2-1 μm, a (TiAlN+Al₂O₃) multilayer with a sublayer thickness of each of TiAlN and Al₂O₃ of 0.1-0.2 μm, a TiAlN layer of 0.3-0.7 μm and an outer layer sequence of Al/Al₂O₃/ZIN with sublayer thicknesses 10-30 nm/10-30 nm/50-100 nm.

13. The coated cutting tool of claim 1, wherein the coating is a CVD coating.

14. The coated cutting tool of claim 13, wherein the coating includes a lower TiN layer with a thickness 0.05-2 μm, a TiAlN layer with a thickness of 1-14 μm, preferably the coating also comprises an upper TiN layer with a thickness of 0.05-2 μm.

15. The coated cutting tool of claim 1, wherein the coated cutting tool is a cutting tool insert, a drill, or a solid end-mill, for metal machining.
